(19) United States
(12) Patent Application Publication
(10) Pub. No.: US 2019/0044021 A1
(43) Pub. Date: Feb. 7, 2019

(54) APPARATUS FOR PROCESSING OF A SOLAR CELL SUBSTRATE, SYSTEM FOR PROCESSING OF A SOLAR CELL SUBSTRATE AND METHOD FOR PROCESSING OF A SOLAR CELL SUBSTRATE

(71) Applicant: APPLIED MATERIALS ITALIA S.R.L., San Biagio di Callatta (IT)

(72) Inventors: Andrea BACCINI, Mignagola di Carbonera (TV) (IT); Daniele GISLON, Venice (IT); Luigi DE SANTI, Spresiano (TV) (IT); Marco GALIAZZO, Quinto Di (IT); Matteo BERTAZZO, Molvena, Vicenza (IT)

(21) Appl. No.: 16/068,641

(22) PCT Filed: Feb. 22, 2016
(86) PCT No.: PCT/EP2016/053663

§ 371 Date: Jul. 6, 2018

(51) Int. Cl. H01L 31/18; H01L 21/67

(52) U.S. Cl. CPC H01L 31/1864; H01L 21/67103

(57) ABSTRACT

The present disclosure provides an apparatus for processing of a solar cell substrate. The apparatus includes at least one thermal device having a support surface configured for supporting and contacting the solar cell substrate, wherein the at least one thermal device is configured for conduction heat transfer.

### FIELD

Embodiments of the present disclosure relate to an apparatus for processing of a solar cell substrate, a system for processing of a solar cell substrate, and a method for processing of a solar cell substrate. Embodiments of the present disclosure particularly relate to an apparatus, system and method for manufacturing of a solar cell, and further relate to an apparatus, system and method for drying of a printing material on a solar cell substrate.

### BACKGROUND

Solar cells are photovoltaic devices that convert sunlight directly into electrical power. Within this field, it is known to manufacture solar cells on a solar cell substrate such as a crystalline silicon base using printing techniques, such as screen printing, achieving on one or more surfaces of the solar cell substrate structures of conductive line patterns, such as selective emitters. During the manufacture of the solar cell, a thermal treatment process can be used, for example, to dry the printed structures of the conductive line patterns.

In order to provide high-quality solar cells, well-defined thermal treatment processes are beneficial, for example, in manufacturing processes. Further, apparatuses and systems for processing of solar cell substrates should provide a high throughput.

In view of the above, new apparatuses, systems, and methods for processing of a solar cell substrate that overcome at least some of the problems in the art are beneficial. Specifically, apparatuses, systems and methods are beneficial that provide improved thermal treatment processes for a solar cell substrate, for example, during manufacturing. Further, apparatuses, systems and methods are beneficial that provide an increased throughput.

### SUMMARY

In light of the above, an apparatus for processing of a solar cell substrate, a system for processing of a solar cell substrate, and a method for processing of a solar cell substrate are provided. Further aspects, benefits, and features of the present disclosure are apparent from the claims, the description, and the accompanying drawings.

According to an aspect of the present disclosure, an apparatus for processing of a solar cell substrate is provided. The apparatus includes at least one thermal device having a support surface configured for supporting and contacting the solar cell substrate, wherein the at least one thermal device is configured for conduction heat transfer.

According to a further aspect of the present disclosure, a system for processing of a solar cell substrate is provided. The system includes the apparatus for processing of a solar cell substrate according to the embodiments described herein. The system further includes a loading station configured for loading the solar cell substrate into the apparatus, and an unloading station configured for unloading the solar cell substrate from the apparatus.

According to a yet further aspect of the present disclosure, a method for processing of a solar cell substrate is provided. The method includes a performing of a first thermal treatment of the solar cell substrate using a first thermal device providing conduction heat transfer while the solar cell substrate is positioned on a support surface of the first thermal device.

According to another aspect of the present disclosure, an apparatus for processing of a solar cell substrate is provided. The apparatus includes two or more thermal devices configured for contacting the solar cell substrate, wherein the two or more thermal devices are configured for conduction heat transfer, and a transport device configured for transportation of the solar cell substrate from a first thermal device of the two or more thermal devices to a second thermal device of the two or more thermal devices.

According to a yet further aspect of the present disclosure, a method for processing of a solar cell substrate is provided. The method includes performing of a first thermal treatment of the solar cell substrate using a first thermal device providing conduction heat transfer, transporting of the solar cell substrate from the first thermal device to a second thermal device, and performing of a second thermal treatment of the solar cell substrate using the second thermal device providing conduction heat transfer.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIGS. 1A and B show schematic views of an apparatus for processing of a solar cell substrate according to embodiments described herein;

FIG. 2A shows a perspective view of an apparatus for processing of a solar cell substrate according to further embodiments described herein;

FIG. 2B shows a schematic view of an apparatus for processing of a solar cell substrate according to yet further embodiments described herein;

FIG. 3 shows a schematic view of an apparatus for processing of a solar cell substrate having a transport device according to embodiments described herein;

FIG. 4 shows a schematic view of an apparatus for processing of a solar cell substrate according to yet further embodiments described herein;

FIG. 5 shows a perspective view of a thermal device of the apparatus for processing of a solar cell substrate according to embodiments described herein;

FIG. 6 shows a schematic top view of a thermal device of the apparatus for processing of a solar cell substrate according to further embodiments described herein;

FIG. 7A illustrates a transport device for the apparatus for processing of a solar cell substrate according to embodiments described herein;

FIG. 7B illustrates another transport device for the apparatus for processing of a solar cell substrate according to embodiments described herein;

FIG. 8 shows a schematic view of a system for processing of a solar cell substrate according to embodiments described herein;

FIG. 9 shows a schematic view of a system for processing of a solar cell substrate according to further embodiments described herein; and

FIG. 10 shows a flow chart of a method for processing of a solar cell substrate according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Solar cell substrates can undergo a thermal treatment, for example, during a manufacturing process of a solar cell or photovoltaic device and/or a regeneration process of a solar cell or photovoltaic device. As an example, a thermal treatment process can be used during the manufacturing process to dry structures printed on the solar cell substrate used in the manufacture of the solar cell or photovoltaic device. Further, thermal treatment processes can be used in the regeneration of solar cells or photovoltaic devices to at least partially restore an efficiency of the solar cell, for example, a conversion efficiency.

According to the present disclosure, a thermal device providing for conduction heat transfer is used to heat and/or cool the solar cell substrate. The conduction heat transfer allows for a fast and controlled heating and/or cooling of the solar cell substrate. Specifically, the solar cell substrate can be precisely and stably kept at a target temperature. The thermal treatment using the conduction heat transfer allows for improved processes, such as an improved manufacturing process and an improved regeneration process. As an example, the conduction heat transfer allows for a reduction of a processing time. A throughput of apparatuses and systems for processing of solar cells substrates can be increased. Further, the conduction heating can reduce power consumption and save energy. In some implementations, the present disclosure uses gas outlets near or adjacent to the thermal devices to blow a gas, such as air, across a surface of the solar cell substrate, e.g., the top of the solar cell substrate. The gas stream can remove evaporations, such as solvent, originating from the drying printing material. Moreover, the gas stream can further minimize a temperature gradient during the heating and/or cooling of the solar cell substrate.

Heat transfer is the exchange of thermal energy between the solar cell substrate and a thermal device, such as a heating device or a cooling device. The modes of heat transfer are conduction, convection and radiation. The present disclosure uses thermal devices configured for conduction heat transfer between the solar cell substrate and the thermal device. The solar cell substrate and the thermal device are in physical contact, for example, in mechanical contact, such that conduction heat transfer can take place. The conduction heat transfer occurs due to a temperature gradient between the solar cell substrate and the thermal device. The solar cell substrate can be heated or cooled using the conduction heat transfer.

The term “solar cell substrate” as used throughout the present disclosure shall embrace solar cell substrates during a manufacturing process (e.g., unfinished solar cells) and solar cell substrates of photovoltaic devices, such as (finished) solar cells. In some implementations, the terms “solar cell substrate” and “solar cell” or “photovoltaic device” can be synonymously used.

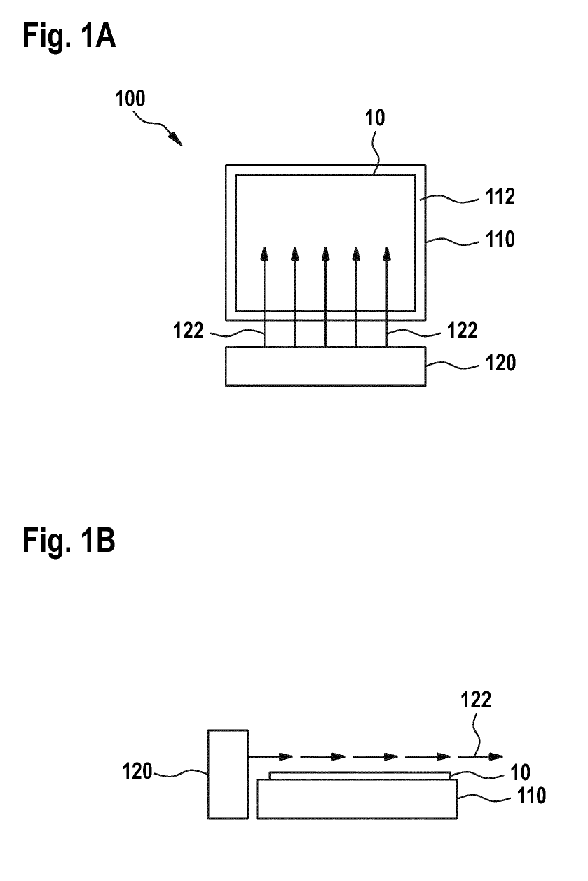

FIG. 1 shows a schematic view of an apparatus 100 for processing of a solar cell substrate 10 according to embodiments described herein.

The apparatus 100 includes at least one thermal device 110 configured for contacting the solar cell substrate 10, wherein the at least one thermal device 110 is configured for conduction heat transfer. The at least one thermal device 110 has a support surface 112 configured to support the solar cell substrate 10. Further, the support surface 112 is configured to (mechanically) contact the solar cell substrate 10 to provide for the conduction heat transfer.

According to some embodiments, the apparatus includes at least one gas outlet provided at the at least one thermal device 110. The gas outlet 120 is configured to direct a gas stream 122 along or across at least a portion of the solar cell substrate 10. The at least a portion of the solar cell substrate 10 can be a surface of the solar cell substrate 10, for example, a surface on which printing material has been deposited. According to some embodiments, which can be combined with other embodiments described herein, the gas is air and the gas stream is an air stream.

The gas outlet 120 can be provided near, or adjacent to, the at least one thermal device 110. As an example, a distance between the gas outlet 120 and the at least one thermal device 110 can be less than 20 cm, specifically less than 10 cm, and more specifically less than 5 cm. In some implementations, the gas outlet 120 can extend along the at least one thermal device 110 such that the gas stream can be provided for substantially the whole surface of the solar cell substrate 10.

The at least one thermal device 110 is configured for mechanically contacting the solar cell substrate 10, wherein the at least one thermal device 110 is configured for conduction heat transfer. The mechanical (or physical) contact between the at least one thermal device 110, particularly the support surface 112, and the solar cell substrate 10 provides for the conduction heat transfer. In some implementations, the at least one thermal device 110 includes at least one heating device configured for heating the solar cell substrate 10.

The at least one thermal device 110 includes at least one of a heating device and a cooling device configured for conduction heat transfer. According to some embodiments, which can be combined with other embodiments described herein, the heating device is a hot plate. The cooling device can include, or be, a cold plate.

The solar cell substrate 10 can have a lower surface and an upper surface opposite the lower surface. Conductive lines, such as fingers and/or busbars of the solar cell can be provided on the upper surface of the solar cell substrate 10. However, the present disclosure is not limited thereto and at least some of the conductive lines can be provided on the lower surface of the solar cell substrate 10. The apparatus 100 can be configured to direct the gas stream 122 along the lower surface and/or the upper surface of the solar cell substrate 10, in particular along substantially the whole lower surface and/or upper surface.

According to some embodiments, which can be combined with other embodiments described herein, the support surface 112 can be configured to mechanically contact a surface of the solar cell substrate 10, for example, the lower surface of the solar cell substrate 10. The mechanical contact, such as a wide-area contact or full-area contact, can provide for the conduction heat transfer between the solar cell substrate 10 and the thermal device on which the solar cell substrate 10 rests. In some implementations, the support surface 112 is configured to contact or cover at least 50%, specifically at least 80%, and more specifically 100% (i.e., the whole) of the surface of the solar cell substrate 10, for example, the lower surface of the solar cell substrate 10.

According to some embodiments, which can be combined with other embodiments described herein, the heating device, and particularly the support surface 112 thereof, can be configured to provide a temperature of at least 100° C., at least 200° C., and more specifically at least 300° C. As an example, the heating device, and particularly the support surface 112 thereof, can be configured to provide a temperature in a range between 100° C. and 500° C., and more specifically in a range between 100° C. and 250° C. In some implementations, the heating device, and particularly the support surface 112 thereof, can be configured to provide a temperature of about 140° C. and/or about 220° C.

According to some embodiments, which can be combined with other embodiments described herein, the apparatus 100 is configured to provide the gas stream 122 having a temperature in a range of between 10° C. and 100° C., specifically in a range of between 20° C. and 50° C., and more specifically in a range of between 20° C. and 30° C. As an example, the apparatus 100 can include one or more heaters configured to heat the gas exiting the gas outlet 120.

According to some embodiments, which can be combined with other embodiments described herein, the apparatus 100 is configured for at least one of drying a deposition material on the solar cell substrate 10, removing evaporations originating from the solar cell substrate 10, and regenerating of a photovoltaic device including the solar cell substrate 10. The photovoltaic device can also be referred to as “solar cell”.

As an example, a deposition process, such as a screen printing process can be performed to deposit conductive line patterns, such as selective emitters, on the solar cell substrate 10, for example, on the upper surface. After the deposition process, the solar cell substrate 10 can be transferred to the at least one thermal device 110 to dry the printed structures of the conductive line patterns using the conduction heat transfer and the gas stream 122. In some implementations, the solar cell substrate 10 can be sequentially positioned on the two or more thermal devices, such as a first heating device and a second heating device, in order to dry the printed structures.

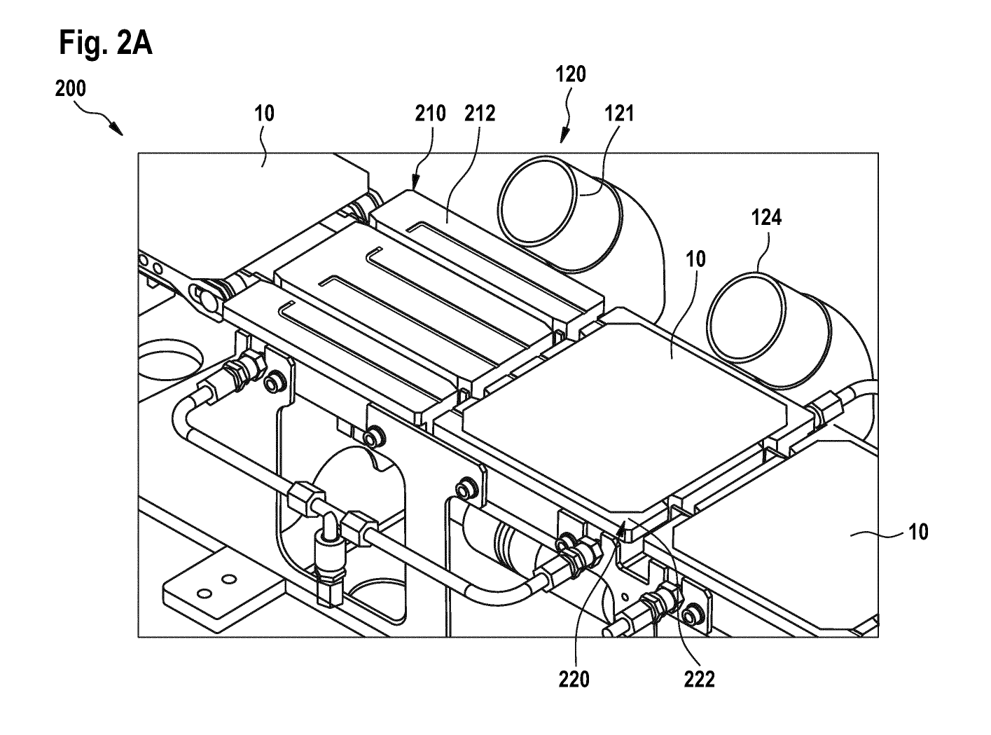

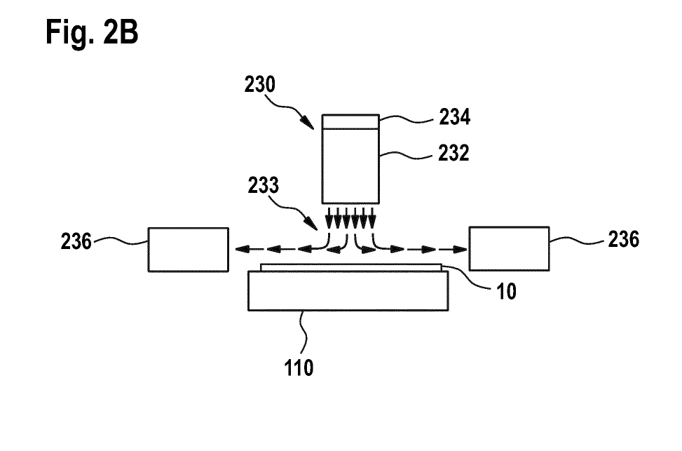

FIG. 2A shows a perspective view of an apparatus 200 for processing of a solar cell substrate 10 according to further embodiments described herein.

According to some embodiments, which can be combined with other embodiments described herein, the at least one thermal device can be two or more thermal devices. The two or more thermal devices can include at least a first thermal device 210 and a second thermal device 220. Each of the two or more thermal devices can have a respective support surface configured for supporting the solar cell substrate 10. As an example, the first thermal device 210 can include a first support surface 212 and the second thermal device 220 can include a second support surface 222.

In some implementations, the at least one gas outlet can be two or more gas outlets. The two or more gas outlets can include at least a first gas outlet 121 and a second gas outlet 124. Each thermal device, and specifically each heating device, can be provided with a respective gas outlet. As an example, the first gas outlet 121 is provided at or adjacent to the first thermal device 210. The second gas outlet 124 is provided at or adjacent to the second thermal device 220.

As exemplarily shown in the example of FIG. 2A, according to some embodiments, the at least one gas outlet can be a conduit or tube having an opening at the at least one thermal device such that the gas stream exiting the at least one gas outlet through the opening can be directed towards the at least one thermal device, and specifically a solar cell substrate 10 positioned on the at least one thermal device.

FIG. 2B shows a perspective view of an apparatus for processing of a solar cell substrate 10 according to yet further embodiments described herein.

According to some embodiments, which can be combined with other embodiments described herein, the apparatus includes a gas distribution arrangement 230. The gas distribution arrangement 230 has the one or more gas outlets 232 and one or more gas inlets 236. The one or more gas outlets 232 are configured to direct the gas stream 233 along or across at least a portion of the solar cell substrate 10. The one or more gas inlets 236 are configured to suck in at least a portion of the gas of the gas stream 233 that has been directed along or across the portion of the solar cell substrate 10. A gas flow from the one or more gas outlets 232 to the one or more gas inlets 236 via the solar cell substrate 10 can be provided. In some implementations, the gas distribution arrangement 230 has one or more blowers or fans 234 at the one or more gas outlets 232 to generate the gas stream 233.

The one or more gas outlets 232 and the one or more gas inlets 236 can be positioned relative to the at least one thermal device 110 such that the gas stream 233 is directed along or across at least a portion of the solar cell substrate 10 while the gas stream 233 flows from the one or more gas outlets 232 to the one or more gas inlets 236. As an example, the one or more gas outlets 232 can be provided above (or facing) the support surface 112 and/or the solar cell substrate 10. The one or more gas inlets 236 can be provided adjacent to the support surface 112 and/or the solar cell substrate 10, e.g., lateral at the support surface 112 or at a side of the support surface 112 or thermal device. In some embodiments, one gas outlet and two gas inlets are provided at a (e.g., each) thermal device. As an example, the gas outlet can be provided above the support surface 112, and the two gas inlets can be provided on opposite sides of the support surface 112, as it is shown in the example of FIG. 2B.

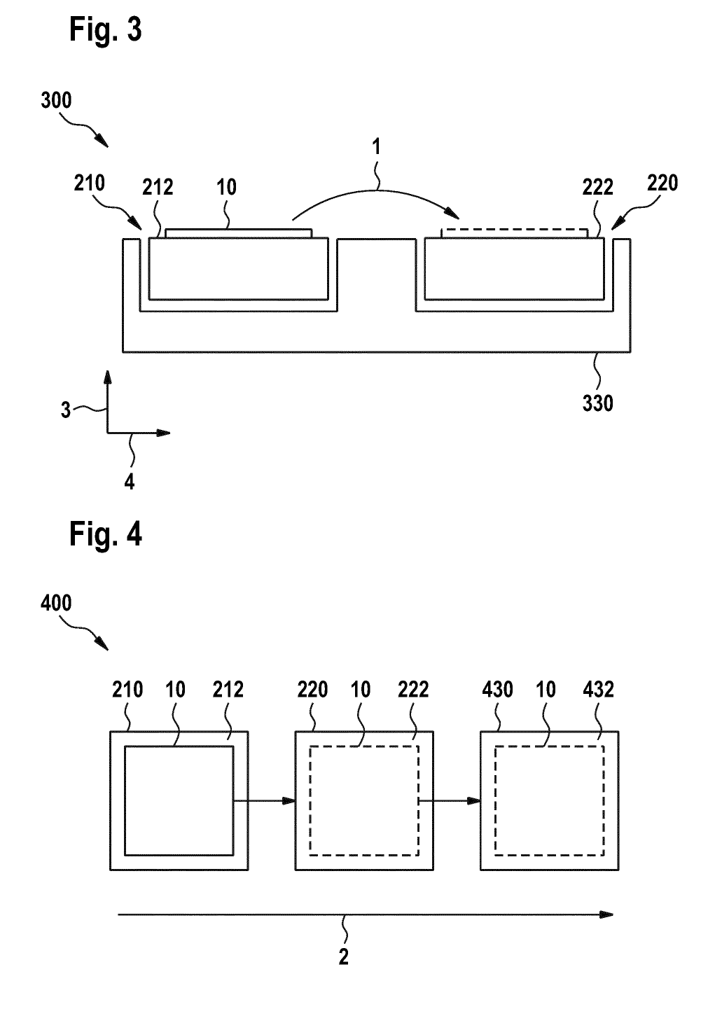

FIG. 3 shows a schematic view of an apparatus 300 for processing of a solar cell substrate 10 according to further embodiments described herein. Although not shown, it is to be understood that the apparatus 300 can optionally include the at least one gas outlet described above.

According to some embodiments, which can be combined with other embodiments described therein, the apparatus of the present disclosure includes a transport device configured for transportation of the solar cell substrate. In particular, the transport device can be configured for at least one of transportation of the solar cell substrate onto the at least one thermal device and moving the solar cell substrate away from the at least one thermal device.

In some implementations, the apparatus 300 includes two or more thermal devices configured for contacting the solar cell substrate 10, wherein the two or more thermal devices are configured for conduction heat transfer, and the transport device 330 configured for transportation (indicated with arrow 1) of the solar cell substrate 10 from a first thermal device 210 of the two or more thermal devices to a second thermal device 220 of the two or more thermal devices.

In some embodiments, the two or more thermal devices include, or are, two or more heating devices. As an example, the first thermal device 210 can be a first heating device of the two or more thermal devices, and the second thermal device 220 can be a second heating device of the two or more thermal devices. This configuration can be used, for example, when the apparatus is configured for drying deposition material on the solar cell substrate 10.

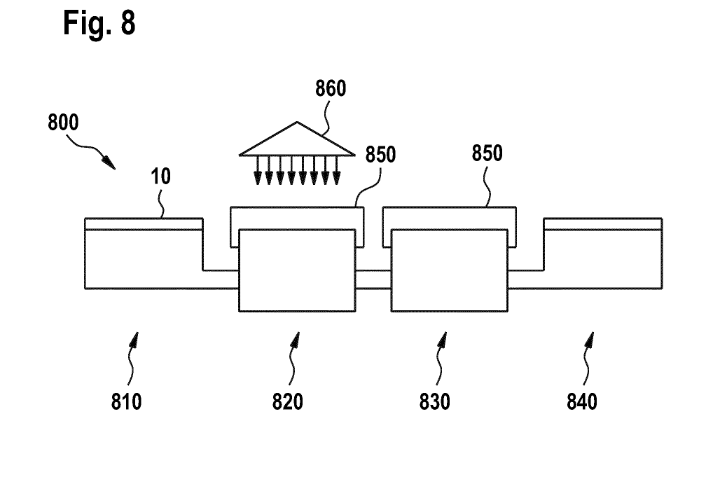

According to some embodiments, the first thermal device 210 can be a first heating device of the two or more thermal devices, and the second thermal device 220 can be a first cooling device of the two or more thermal devices. This configuration can be used, for example, when the apparatus 300 is configured for regeneration of a photovoltaic device including the solar cell substrate 10. The regeneration of the photovoltaic device is further explained with respect to FIG. 8.

In some implementations, all thermal devices of the apparatus 300, and specifically all heating devices, can provide substantially the same temperature. In other implementations, at least some of the thermal devices of the apparatus 300, and specifically of the heating devices, can provide different temperatures.

According to some embodiments, which can be combined with other embodiments described herein, the transport device 330 includes one or more movement units configured for contacting the solar cell substrate 10. As an example, the one or more movement units can be configured for lifting the solar cell substrate 10 from the first thermal device 210 and transferring the solar cell substrate 10 to the second thermal device 220. In some implementations, the transport device 330 can be configured to transport the solar cell substrate 10 sequentially from one thermal device to a next or adjacent thermal device, for example, to move or convey the solar cell substrate 10 along a transportation path.

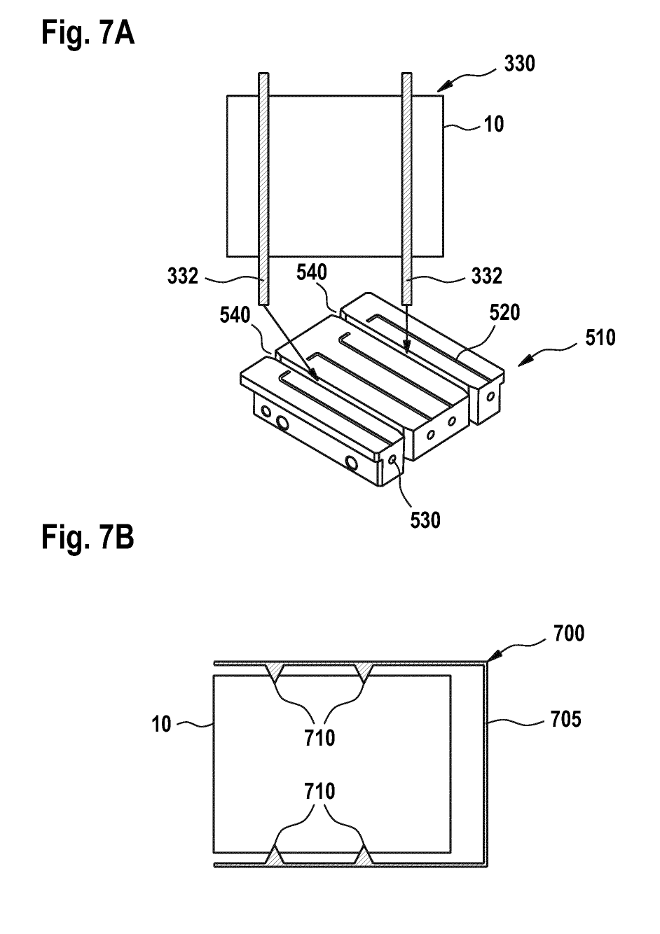

According to some embodiments, the transport device 330, e.g., the one or more movement units, is configured to move the solar cell substrate 10 in a vertical direction 3 and a horizontal direction 4 to lift the solar cell substrate 10 and to move the solar cell substrate 10 between two thermal devices, such as from the first thermal device 210 to the second thermal device 220. The term “vertical direction” is understood to distinguish over “horizontal direction”. The vertical direction 3 can be substantially parallel to the force of gravity. The transport device 330 is further explained with respect to FIGS. 7A and B.

FIG. 4 shows a schematic top view of an apparatus 400 for processing of a solar cell substrate 10 according to further embodiments described herein.

According to some embodiments, which can be combined with other embodiments described herein, the two or more thermal devices are arranged in a row along a transportation path 2 provided by the transport device (not shown). As an example, the two or more thermal devices can provide a sequence of, for example, hot plates and/or cold plates in an in-line processing system. The solar cell substrate 10 can be transported or conveyed along the transportation path 2 from one thermal device to another (for example, an adjacent or next) thermal device. The transportation of the solar cell substrate 10 from one thermal device to another thermal device can reduce a wait time or stop time of the solar cell substrate 10 at a thermal processing station. In particular, a stop time of the solar cell substrate 10 at the individual thermal devices can be reduced. A quasi-continuous transport flow, for example, in an in-line processing system, can be provided. A throughput of the processing system can be increased.

According to some embodiments, which can be combined with other embodiments described herein, the two or more thermal devices include one or more cooling devices 430 configured for cooling of the solar cell substrate 10, for example, heated by a heating device. The one or more cooling device 430 are configured for at least one of conduction heat transfer and convection heat transfer. In some implementations, the one or more cooling devices 430 are cold plates configured for conduction heat transfer. According to some embodiments, the one or more cooling devices are provided at the end of a sequence of thermal devices. As an example, the one or more cooling devices 430 can be provided at the end of the transportation path 2 provided by the transport device.

In some implementations, the one or more cooling devices 430 can each have a support surface 432 configured to support the solar cell substrate 10. The support surface 432 can be configured to mechanically contact a surface of the solar cell substrate 10, for example, the lower surface of the solar cell substrate 10. The mechanical contact, such as a wide-area contact or full-area contact, can provide for the conduction heat transfer between the solar cell substrate 10 and the cooling device on which the solar cell substrate 10 rests. The one or more cooling devices 430 can be water-cooled devices. Additionally or alternatively, a convective cooling, for example, using an airflow, can be used to improve an efficiency of the cooling process of the solar cell substrate 10.

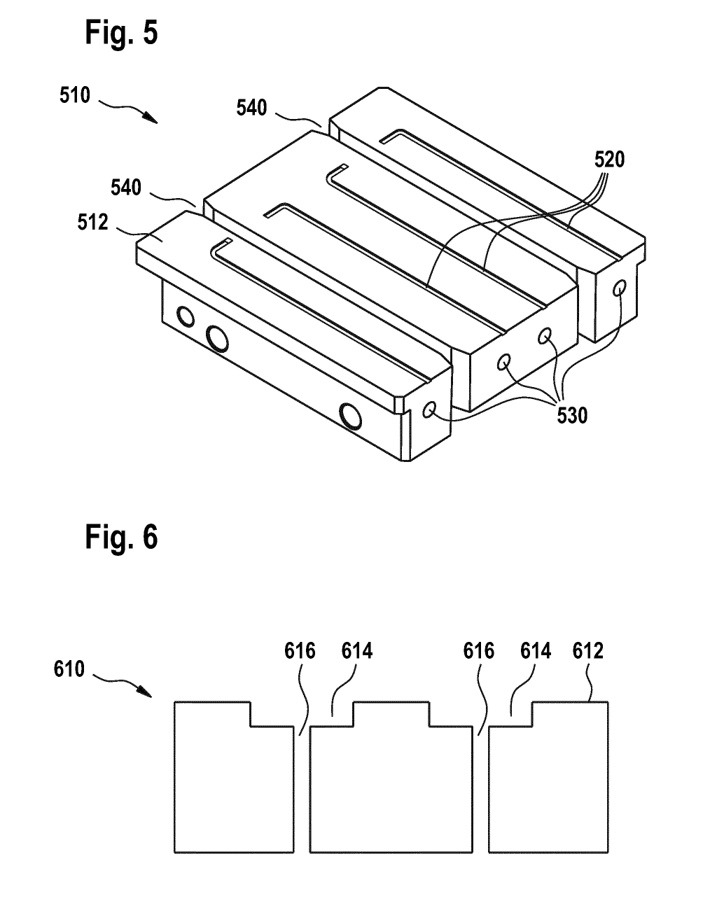

FIG. 5 shows a perspective view of a thermal device 510 of the apparatus for processing of a solar cell substrate according to embodiments described herein.

According to some embodiments, which can be combined with other embodiments described herein, the apparatus, and specifically the thermal device 510, includes a holding arrangement configured for holding the solar cell substrate at the at least one thermal device 510. In some implementations, the holding arrangement can be configured as a vacuum chuck. As an example, the holding arrangement can include one or more recesses 520 on the support surface 512. An under pressure can be provided in the one or more recesses 520 such that the solar cell substrate can be held at the support surface 512. An embodiment of the holding arrangement is further explained with respect to FIG. 6.

According to some embodiments, the holding arrangement includes an electrostatic device configured to provide an electrostatic force for holding the solar cell substrate. As an example, the at least one thermal device 510 is configured as an electrostatic chuck (E-chuck). The E-chuck can have the support surface 512 for supporting the solar cell substrate thereon. In one embodiment, the E-chuck includes a dielectric body having electrodes embedded therein. The dielectric body can be fabricated from a dielectric material, preferably a high thermal conductivity dielectric material such as pyrolytic boron nitride, aluminum nitride, silicon nitride, alumina or an equivalent material. The electrodes may be coupled to a power source, which provides power to the electrode to control a chucking force. The chucking force is an electrostatic force acting on the solar cell substrate to fix the solar cell substrate on the support surface 512.

In some implementations, the at least one thermal device 510 is a heating device or hot plate and can include one or more holes 530 configured for insertion of one or more heating units, such as heating rods or heating bars. As an example, the one or more heating units can be removably inserted into respective holes to provide for the heating of the at least one thermal device 510. The one or more heating units can be electrical heating units.

According to some embodiments, the at least one thermal device 510 can include one or more recesses 540. The one or more recesses 540 can be configured such that the transport device, and particularly the one or more movement units, can pass therethrough for contacting and moving the solar cell substrate as described with respect to FIGS. 3 and 4.

FIG. 6 shows a cross-sectional side view of a thermal device 610 of the apparatus for processing of a solar cell substrate according to further embodiments described herein. The thermal device 610 has the support surface 612 configured for supporting the solar cell substrate (not shown).

According to some embodiments, which can be combined with other embodiments described herein, the apparatus, and specifically the thermal device 610, includes a holding arrangement configured for holding the solar cell substrate at the at least one thermal device 610. The holding arrangement can include one or more suction devices configured to provide a suction force for holding the solar cell substrate, for example, at the support surface 612. In some implementations, the at least one thermal device 610 can be configured as a “vacuum chuck”. The vacuum chuck allows for at least one of an improved temperature control and temperature uniformity.

The one or more suction devices can include at least one of suction holes and recesses in the support surface 612. According to some embodiments, one or more suction holes 616 are provided on the support surface 612. The one or more suction holes 616 can be configured to connect the support surface 612 with suction units, such as a vacuum pump. In some implementations, one or more recesses 614 can be provided on the support surface 612 of the at least one thermal device 610. The one or more suction holes 616 can be positioned in the one or more recesses 614, for example, to connect the one or more recesses 614 with the suction unit. The one or more recesses 614 provide for an increased contact region between the solar cell substrate and a region of under pressure in the one or more recesses 614 to securely hold the solar cell substrate at the support surface 612.

According to some embodiments, which can be combined with other embodiments described herein, the at least one thermal device includes stress release devices (not shown) configured to reduce or avoid thermal stress acting on the solar cell substrate. Specifically, the stress release devices can be configured to accommodate or compensate at least one of a thermal expansion and thermal contraction (negative thermal expansion) of the at least one thermal device. A thermal stress, for example, a mechanical stress, acting on the solar cell substrate due to heating and/or cooling can be reduced. Damage, such as breakage, of the solar cell substrate can be reduced or even avoided.

In some implementations, the stress release devices can be provided as recesses or cutouts on the support surface of the at least one thermal device. At least one of thermal expansion and thermal contraction e.g. of the material providing the support surface can be compensated for by the recesses or cutouts. As an example, the stress release devices can have one or more first stress release devices and one or more second stress release devices. The one or more first stress release devices can be substantially parallel to each other and the one or more second stress release devices can be substantially parallel to each other. The one or more first stress release devices can extend lengthwise in a first direction and the one or more second stress release devices can extend lengthwise in a second direction. The first direction and the second direction can be non-parallel to each other. As an example, the first direction and the second direction can be substantially perpendicular to each other. The first direction and the second direction can define a substantially horizontal plane. According to some embodiments, the one or more first stress release devices and the one or more second stress release devices can form a pattern such as a grid on the support surface of the at least one thermal device.

FIG. 7A illustrates a transport device for the apparatus for processing of a solar cell substrate according to embodiments described herein. FIG. 7B illustrates another transport device for the apparatus for processing of a solar cell substrate according to embodiments described herein. The transport device according to the embodiments described herein is an external transport device which can reduce an impact of the transport device hardware on the heating process.

According to some embodiments, which can be combined with other embodiments described herein, the transport device 330 includes one or more movement units configured for contacting the solar cell substrate 10, such as the lower surface (FIG. 7A) or an edge of the lower surface of the solar cell substrate 10 (FIG. 7B), to lift and transport the solar cell substrate 10. As an example, the one or more movement units can be configured for lifting the solar cell substrate 10 from the first thermal device and transferring the solar cell substrate 10 to the second thermal device. In some implementations, the transport device 330 can be configured to transport the solar cell substrate 10 sequentially from one thermal device to a next or adjacent thermal device, for example, to move or convey the solar cell substrate 10 along a transportation path. In some implementations, the transport device 330 is provided below the solar cell substrate 10 and not above the solar cell substrate 10. The space above the solar cell substrate 10 can be utilized otherwise, for example, by installing one or more radiation devices used in a regeneration process.

According to some embodiments, the transport device 330, e.g., the one or more movement units, is configured to move the solar cell substrate 10 in a vertical direction and a horizontal direction to lift the solar cell substrate 10 and to move the solar cell substrate between two thermal devices, such as from the first thermal device to the second thermal device. The term “vertical direction” is understood to distinguish over “horizontal direction”. The vertical direction can be substantially parallel to the force of gravity.

In some implementations, the transport device 330 can be configured to sequentially or simultaneously move the solar cell substrate 10 in the vertical direction and the horizontal direction along a movement path. The movement path can lie in a movement plane defined by the vertical direction and the horizontal direction. In particular, the movement plane can be a substantially vertically oriented plane. According to some embodiments, the transport device 330 can simultaneously move the solar cell substrate 10 in the vertical direction and the horizontal direction such that the solar cell substrate 10 is transported from the first thermal device to the second thermal device along an arc-shaped movement path. A respective movement unit of the transport device 330 can be provided between two adjacent thermal devices. In particular, the movement units can be provided at fixed positions with respect to the two or more thermal devices.

A deposition process, such as a screen printing process can be performed to deposit conductive line patterns, such as selective emitters, on the solar cell substrate 10, for example, on the upper surface. After the deposition process, the solar cell substrate 10 can be transferred to the at least one thermal device to dry the printed structures of the conductive line patterns using the conduction heat transfer and the gas stream. In some implementations, the solar cell substrate 10 can be sequentially positioned on the two or more thermal devices, such as a first heating device and a second heating device, in order to dry the printed structures.

Referring to FIG. 7A, the one or more movement units can be configured as “tooth-saw mechanisms” that lift and move the solar cell substrate 10 from one thermal device to a next or adjacent thermal device. Specifically, the movement units can be “walking beams” 332 that can pass through the one or more recesses 540 of the at least one thermal device 110 to lift the solar cell substrate 10 for transportation. No belt or other continuous conveyor mechanism is used, since the stationary movement units can lift and transfer the solar cell substrate 10 between adjacent thermal devices.

Referring to FIG. 7B, a transport device 700 according to further embodiments is shown. The one or more movement units of the transport device 700 include one or more contact pins 710 configured for contacting an edge portion of the bottom side or lower side of the solar cell substrate 10. The one or more contact pins 710 can be provided on a frame 705 of the transport device 700. The frame can be configured to at least partially surround the at least one thermal device and/or the solar cell substrate 10. The one or more contact pins 710 use small contact points between the transport device 700 and the solar cell substrate 10, further reducing an impact of the transport device hardware on the heating process.

FIG. 8 shows a schematic view of a system 800 for processing of a solar cell substrate according to embodiments described herein. The system 800 can be part of an in-line processing system, for example, configured for manufacturing and/or regeneration of a solar cell substrate.

The system 800 includes an apparatus for processing of a solar cell substrate. The apparatus can be configured according to the embodiments described herein. Specifically, the apparatus can include a first thermal device 820, a second thermal device 830, and gas outlets 850. Further, the system 800 includes a loading station 810 configured for loading the solar cell substrate into the apparatus, and an unloading station 840 configured for unloading the solar cell substrate from the apparatus.

According to some embodiments, the apparatus is configured for regeneration of a photovoltaic device including the solar cell substrate 10. The photovoltaic device can also be referred to as “solar cell”. In particular, some solar cells experience a reduction in efficiency, for example, during the initial operating time, due to the formation of defects in the solar cell. This phenomenon is particularly known as “carrier induced degradation” or “light induced degradation”. Such a degradation particularly occurs in c-Si cells or PERC (Passivated Emitter Rear Cell) cells. Thermal treatment processes can be used to at least partially restore the efficiency. As an example, the efficiency can be at least partially restored by simultaneously heating and illuminating the solar cell followed by a fast cooling.

According to some embodiments, which can be combined with other embodiments described herein, the apparatus includes one or more radiation devices 860 configured to irradiate the photovoltaic device/solar cell substrate. As an example, the one or more radiation devices 860 are configured to irradiate the photovoltaic device during regeneration of the photovoltaic device including the solar cell substrate.

In some implementations, the apparatus includes two or more thermal devices including one or more heating devices (e.g., the first thermal device 820) configured for heating the solar cell substrate 10, wherein the one or more heating device are configured for conduction heat transfer. As an example, the one or more heating devices are hot plates. The apparatus includes one or more cooling devices (e.g., the second thermal device 830). The one or more cooling devices are configured for at least one of conduction heat transfer and convection heat transfer. In some implementations, the one or more cooling devices are cold plates configured for conduction heat transfer.

According to some embodiments, the one or more radiation devices 860 are positioned above at least one heating device of the one or more heating devices such that a solar cell substrate 10 can be irradiated while the solar cell substrate 10 is located on the at least one heating device. In particular, the solar cell substrate 10 can be located between the at least one heating device and the one or more radiation devices 860, for example, during irradiation of the solar cell substrate 10. The solar cell substrate 10 can be simultaneously heated by the one or more heating devices and illuminated by the one or more radiation devices 860.

In some implementations, the one or more radiation devices 860 are configured to emit radiation in the infrared wavelength range. As an example, the infrared wavelength range can consist of wavelengths between 780 nm and 1 mm. In some implementations, the infrared wavelength range is at least one of a short wavelength range, for example, 1.4 to 3 μm, and a mid wavelength range, for example, 3 to 8 μm.

In some implementations, the regeneration process includes a heating of the solar cell substrate 10 at the one or more heating devices to a temperature in a range of between 100 to 300° C., and specifically in a range of between 120 to 250° C. The solar cell substrate 10 is heated by the one or more heating devices while simultaneously being illuminated using the one or more radiation devices 860. As an example, the solar cell substrate 10 can be illuminated with an intensity of at least 2 suns, and specifically at least 3 suns. The intensity provided by 1 sun is approximately 1 kW/m². According to some embodiments, the solar cell substrate 10 can be illuminated for a predetermined period, such as at least 5 seconds, specifically at least 10 seconds, and more specifically at least 60 seconds. As an example, the solar cell substrate 10 can be illuminated for as long as 5 to 60 seconds.

The apparatus includes the transport device (not shown) configured for transportation of the solar cell substrate 10 between the one or more thermal devices, for example, from the one or more heating devices to the one or more cooling devices. In some implementations, the loading station 810 configured for loading the solar cell substrate onto the two or more thermal devices, such as the one or more heating devices, is provided. Further, the unloading station 840 configured for unloading or receiving the solar cell substrate 10 from the two or more thermal devices after thermal processing, such as a regeneration process, can be provided.

The regeneration process using the efficient conduction heat transfer for the heating and optionally the cooling of the solar cell substrate allows for a fast heating ramp up and a fast cooling ramp down, respectively. Power consumption of the apparatus can be reduced. In particular, a power to be installed can be decreased and energy can be saved. Further, a process control of the regeneration process can be improved.

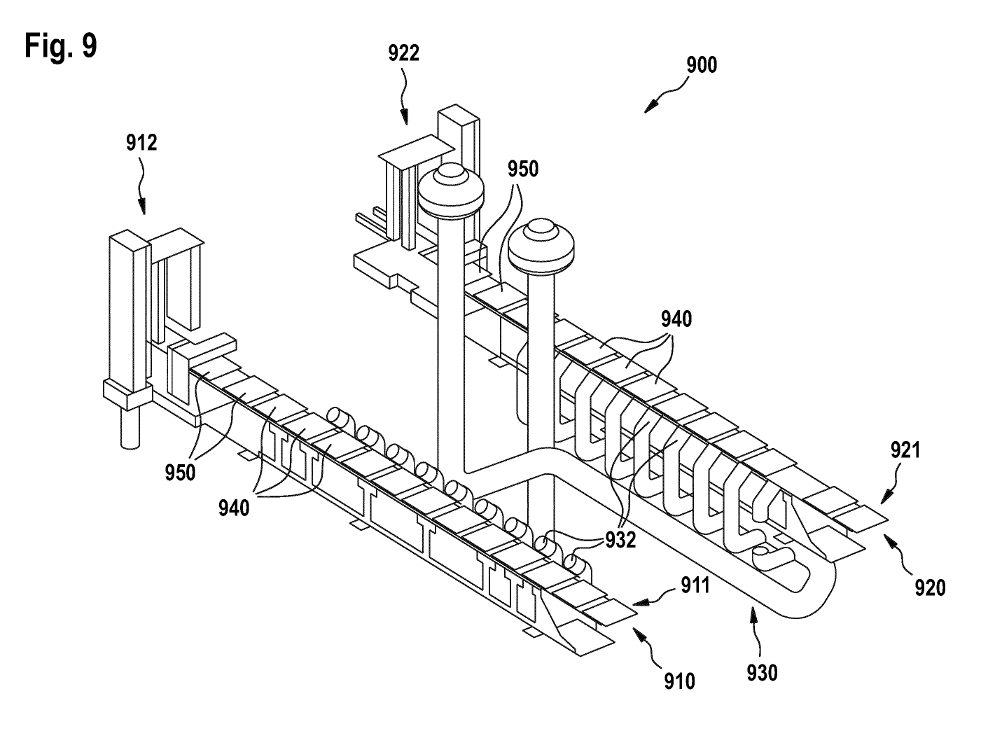

FIG. 9 shows a schematic view of a system 900 for processing of a solar cell substrate 10 according to further embodiments described herein. The system 900 can be part of an in-line processing system, for example, configured for manufacturing and/or regeneration of a solar cell substrate.

The system 900 is a dual-line processing system having a first processing line 910 and a second processing line 920 arranged substantially parallel to each other. However, the present disclosure is not limited thereto, and the system can have more than two processing lines, such as 3 or 4 processing lines arranged in parallel.

The system 900 includes at least one loading station and at least one unloading station. As an example, the first processing line 910 has a first loading station 911 and a first unloading station 912. The second processing line 920 has a second loading station 921 and a second unloading station 922. The at least one unloading station, such as the first unloading station 912 and the second unloading station 922, can be offers configured to store a number of solar cell substrate 10, for example, vertically.

According to some embodiments, the system 900 has a gas distribution apparatus 930. The gas distribution arrangement 930 has the one or more gas outlets 932. The one or more gas outlets 932 are provided adjacent to at least some of the thermal devices, such as one or more heating devices 940 and/or one or more cooling devices 950. In some implementations, the one or more gas outlets 932 are only provided at the one or more heating devices 940, but are not provided at the one or more cooling devices 950.

The two or more thermal devices of the apparatus of the present disclosure are arranged in a row (or line) along a transportation path provided by the transport device (e.g., a moving conveyor) of the apparatus. Each of the two or more processing lines, such as the first processing line 910 and the second processing line 920, can provide a respective transportation path. As an example, at least 5, specifically at least 8, and more specifically at least 10 thermal devices can be arranged in the row along the respective transportation path. According to some embodiments, a number of heating devices in a row can be larger than a number of cooling devices. As an example, at least 5, specifically at least 8, and more specifically at least 10 heating devices can be arranged in the row followed by one or two cooling devices.

The system 900 provides for a compact design. In particular, the system 900 has a plurality of rows or lines and solar cell substrates or wafers can be positioned close to one another. A throughput of the system 900, for example, an in-line processing system can be increased.

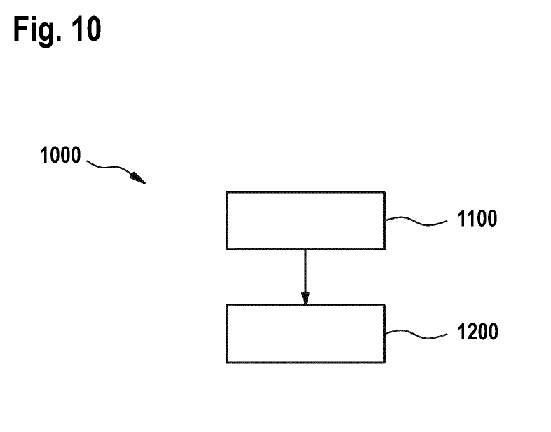

FIG. 10 shows a flow chart of a method 1000 for processing of a solar cell substrate according to embodiments described herein. The method 1000 can be a method for at least one of drying deposition material on the solar cell substrate and regeneration of a photovoltaic device. Specifically, the method 1000 can utilize the apparatuses and systems according to the embodiments described herein.

The method 1000 includes in block 1100 a performing of a first thermal treatment of the solar cell substrate using a first thermal device providing conduction heat transfer while the solar cell substrate is positioned on a support surface of the first thermal device. According to some embodiments, the method 1000 includes in block 1200 a directing of a gas stream along at least a portion of the solar cell substrate while the first thermal treatment is performed. In some implementations, the method 1000 further includes a transporting of the solar cell substrate from the first thermal device to a second thermal device, and a performing of a second thermal treatment of the solar cell substrate using the second thermal device providing conduction heat transfer. A gas stream can be directed along at least a portion of the solar cell substrate while the second thermal treatment is performed. In some implementations, the performing of the first thermal treatment and/or the second thermal treatment can include a heating of the solar cell substrate and/or a cooling of the solar cell substrate.

According to further embodiments, the method for processing of a solar cell substrate includes a performing of the first thermal treatment of the solar cell substrate using the first thermal device providing conduction heat transfer, a transporting of the solar cell substrate from the first thermal device to a second thermal device, and a performing of a second thermal treatment of the solar cell substrate using the second thermal device providing conduction heat transfer.

In the above methods, the first thermal treatment can be a heating treatment. The second thermal treatment can be another heating treatment or a cooling treatment. In some implementations, performing the first thermal treatment includes a heating of the solar cell substrate using the first thermal device being a heating device. The second thermal treatment can include a cooling of the solar cell substrate using the second thermal device being a cooling device. In some implementations, the method according to the embodiments described therein further includes a cooling of the heated solar cell substrate using a first cooling device providing conduction heat transfer.

According to some embodiments, which can be combined with other embodiments described herein, a thermal processing, such as a heating or cooling, of the solar cell substrate 10 on a thermal device can be performed for a predetermined period. A total thermal processing time can correspond to a sum of the predetermined periods of each of the thermal devices on which the solar cell substrate 10 is located to be thermally processed. In some implementations, the predetermined period can be less than 30 seconds, specifically less than 20 seconds, specifically less than 10 seconds, and more specifically less than 5 seconds. The total thermal processing time can be at least 30 seconds, specifically at least one minute, and more specifically at least 2 minutes (please check).

In some implementations, the predetermined period of the thermal processing on each of the thermal devices can correspond to the time during which the solar cell substrate 10 is positioned on the respective thermal device. At least some of the thermal devices can be kept at a constant temperature, and no continuous adjustment, such as a ramping, of the temperature of the thermal devices depending on whether a solar cell substrate 10 is present or not is performed. According to some embodiments, the predetermined period can be substantially the same for all thermal devices. In other embodiments, the predetermined periods can be different for at least some of the thermal devices.

According to some embodiments, at least some of the thermal devices can ramp a temperature up and/or down during the thermal processing of the solar cell substrate 10. As an example, the solar cell substrate 10 can be placed on the thermal device, and the temperature can then be ramped up and/or down to thermally process the solar cell substrate 10.

According to embodiments described herein, the method for processing of a solar cell substrate can be conducted using computer programs, software, computer software products and the interrelated controllers, which can have a CPU, a memory, a user interface, and input and output devices being in communication with the corresponding components of the apparatus and system.

The present disclosure provides for a fast heat transfer between thermal devices and solar cell substrate. Specifically, the hot plates and the vacuum for holding the solar cell substrate at the hot plates provide for such fast heat transfer. A temperature of the solar cell substrate can be kept stably at the set temperature of the hot plate. A drying process can be efficiently conducted. The drying process can be further improved using the gas stream that flows along the solar cell substrate while the thermal treatment is performed. A compact design of the apparatus or system, such as an in-line processing system, can be provided due to multiple rows or lanes in parallel.

While the foregoing is directed to embodiments of the disclosure, other and further embodiments of the disclosure may be devised without departing from the basic scope thereof, and the scope thereof is determined by the claims that follow.

1. Apparatus for processing of a solar cell substrate, comprising:
at least one thermal device having a support surface configured for supporting and contacting the solar cell substrate, wherein the at least one thermal device is configured for conduction heat transfer.

2. The apparatus of claim 1, further including:
at least one gas outlet provided at the at least one thermal device, wherein the at least one gas outlet is configured to direct a gas stream along at least a portion of the solar cell substrate.

3. The apparatus of claim 2, wherein the at least one gas outlet is configured to direct the gas stream along a surface of the solar cell substrate having a printing material thereon.

4. The apparatus of claim 1, wherein the at least one thermal device includes at least one of a heating device and a cooling device.

5. The apparatus of claim 1, wherein the apparatus is configured for at least one of:
drying deposition material on the solar cell substrate;
removing evaporations originating from the solar cell substrate; and
regenerating a photovoltaic device including the solar cell substrate.

6. The apparatus of claim 1, further including a holding arrangement configured for holding the solar cell substrate at the at least one thermal device, wherein the holding arrangement includes at least one of one or more suction devices configured to provide a suction force for holding the solar cell substrate and an electrostatic device configured to provide an electrostatic force for holding the solar cell substrate.

7. The apparatus of claim 6, wherein the one or more suction devices include at least one of one or more suction holes and one or more recesses on the support surface.

8. The apparatus of claim 1, wherein the at least one thermal device includes stress release devices configured to reduce a thermal stress acting on the solar cell substrate.

9. The apparatus of claim 1, further including a transport device configured for transportation of the solar cell substrate, wherein the transport device is configured for at least one of transportation of the solar cell substrate onto the at least one thermal device and moving the solar cell substrate away from the at least one thermal device.

10. The apparatus of claim 9, wherein the at least one thermal device is two or more thermal devices, and wherein the transport device is configured for transportation of the solar cell substrate from a first thermal device of the two or more thermal devices to a second thermal device of the two or more thermal devices.

11. The apparatus of claim 10, wherein the two or more thermal devices are arranged in a row along a transportation path provided by the transport device.

12. The apparatus of claim 9, wherein the transport device includes one or more movement units configured for contacting a lower surface or an edge of the lower surface of the solar cell substrate to move the solar cell substrate.

13. System for processing of a solar cell substrate, comprising:
an apparatus for processing of a solar cell substrate, comprising:
at least one thermal device having a support surface configured for supporting and contacting the solar cell substrate, wherein the at least one thermal device is configured for conduction heat transfer;
a loading station configured for loading the solar cell substrate into the apparatus; and
an unloading station configured for unloading the solar cell substrate from the apparatus.

14. Method for processing of a solar cell substrate, comprising:
performing a first thermal treatment of the solar cell substrate using a first thermal device providing conduction heat transfer while the solar cell substrate is positioned on a support surface of the first thermal device.

15. The method of claim 14, further including:
directing a gas stream along at least a portion of the solar cell substrate while the first thermal treatment is performed.

16. The method of claim 14, further including:
transporting the solar cell substrate from the first thermal device to a second thermal device; and
performing a second thermal treatment of the solar cell substrate using the second thermal device providing conduction heat transfer.

17. The method of claim 16, wherein the performing a first thermal treatment includes a heating of the solar cell substrate.

18. The method of claim 15, wherein performing a second thermal treatment includes a heating of the solar cell substrate.

19. The method of claim 16, wherein the performing a first thermal treatment includes a heating of the solar cell substrate.

20. The method of claim 16, wherein the performing the second thermal treatment includes a heating of the solar cell substrate.
